(19) United States
(12) Patent Application Publication
(10) Pub. No.: US 2011/0031489 A1
(43) Pub. Date: Feb. 10, 2011

(54) COMPLEMENTARY THIN FILM ELECTRONICS BASED ON ZnO/ZnTe

(75) Inventors: Jamie Phillips, Ann Arbor, MI (US); Willie Bowen, Ypsilanti, MI (US); Weiming Wang, Ann Arbor, MI (US)

Correspondence Address: HARNESS, DICKEY & PIERCE, P.L.C., P.O. BOX 828, BLOOMFIELD HILLS, MI, 48303, US

(73) Assignee: The Regents of The University of Michigan, Ann Arbor, MI (US)

(21) Appl. No.: 12/818,423

(22) Filed: Jun. 18, 2010

Related U.S. Application Data
(60) Provisional application No. 61/218,487, filed on Jun. 19, 2009.

(51) Int. Cl. H01L 29/12

(52) U.S. Cl. 257/43; 257/E29.068

(57) ABSTRACT

A complementary thin-film electronic device structure is provided where one of the transistors has a p-type channel region fabricated from zinc telluride material. The device structure further includes another field effect transistor having an n-type channel region disposed adjacent to and operably coupled to the p-type transistor.

### CROSS-REFERENCE TO RELATED APPLICATIONS

This claims the benefit of U.S. Provisional Application No. 61/218,487 filed on Jun. 19, 2009. The entire disclosure of the above application is incorporated herein by reference.

### GOVERNMENT CLAUSE

This invention was made with government support under Grant No. W911NF-07-1-0306 awarded by the Army Research Office. The government has certain rights in this invention.

### FIELD

The present disclosure relates to thin film electronics and, more particularly, to complementary thin film electronics with a transistor having a p-type channel region fabricated from zinc telluride material.

### BACKGROUND

Complementary electronics consisting of thin-film transistors (TFTs) exploit this low-cost technologies' relevance for enabling logic integrated circuits (ICs). This expands the use of TFTs as an entrenched back-plane pixel driving technology for active-matrix liquid crystal displays or active-matrix organic light-emitting-diode emissive displays providing large-area coverage and demonstrates its potential use in elaborate digital structures such as ring oscillators, shift registers, and advanced logic gates (NAND, NOR) for system-on-panel computation on flexible substrates. The CMOS inverter is the basic building block of all digital designs and requires p-channel and n-channel field-effect transistors. Oxide TFTs based on ZnO and InGaZnO have recently received much attention due to relatively high carrier mobilities (>5 cm²/V·s) in comparison to a-Si and organic thin-film counterparts (<1 cm²/V·s). However, these oxide materials are intrinsically n-type due to oxygen vacancies, where p-type thin films are not readily achievable. Recently, hybrid organic-inorganic complementary inverter structures have been demonstrated utilizing n-channel ZnO TFTs and p-channel pentacene TFTs. Therefore, it remains desirable to develop a new purely inorganic complementary inverter. This section provides background information related to the present disclosure which is not necessarily prior art.

### SUMMARY

A complementary thin-film electronic device structure is provided where one of the transistors has a p-type channel region fabricated from zinc telluride material. The device structure further includes another field effect transistor having an n-type channel region disposed adjacent to and operably coupled to the p-type transistor. The device structure may be used as a basis for a purely inorganic complementary inverter.

This section provides a general summary of the disclosure, and is not a comprehensive disclosure of its full scope or all of its features. Further areas of applicability will become apparent from the description provided herein. The description and specific examples in this summary are intended for purposes of illustration only and are not intended to limit the scope of the present disclosure.

### DRAWINGS

FIG. 1 is a perspective view of an exemplary complementary thin-film electronic device structure;

FIG. 2 is a schematic of a complementary inverter circuit;

FIG. 3 is a perspective view on another exemplary complementary thin-film electronic device structure having a highly conductive silicon wafer serving as the gate electrode;

FIG. 4 is a side view of the exemplary complementary thin-film electronic device structure shown in FIG. 3;

FIG. 5 is a top view of the exemplary complementary thin-film electronic device structure shown in FIG. 3;

FIG. 6 is a graph illustrating the drain current-voltage curves for the exemplary complementary thin-film electronic device structure;

FIGS. 7A and 7B are graphs illustrating the transfer characteristics for ZnO and ZnTe transistors, respectively; and

FIGS. 8A and 8B are graphs illustrating voltage gain and switching current, respectively, of the inverter circuit.

The drawings described herein are for illustrative purposes only of selected embodiments and not all possible implementations, and are not intended to limit the scope of the present disclosure. Corresponding reference numerals indicate corresponding parts throughout the several views of the drawings.

### DETAILED DESCRIPTION

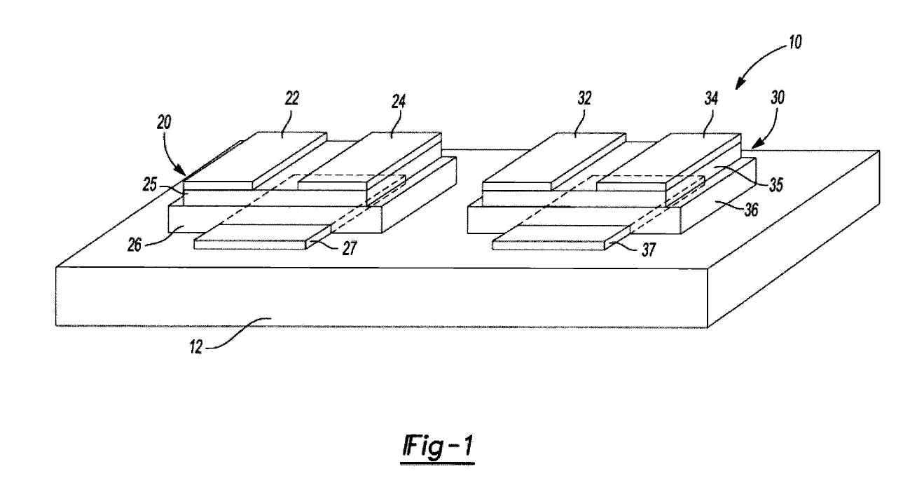

FIG. 1 depicts an exemplary complementary thin-film electronic device structure 10. The device structure 10 is comprised generally of an n-type field effect transistor 20 and a p-type field effect transistor 30 residing on a common substrate 12. The substrate 12 is made from silicon, glass, plastic, or other low-cost suitable substrate material typical for thin film transistors. Each of the field effect transistors 20, 30 is further defined as metal oxide semiconductor transistor (MOSFET) having a source electrode 22, 32, a drain electrode 24, 34, a gate electrode 27 and a channel region, 25, 35. While the following description is provided with reference to MOSFETs, other types of transistors also fall within the broader aspects of this disclosure.

In the exemplary embodiment, the channel region 25 of the n-type field effect transistor 20 is fabricated from zinc oxide (ZnO) material. The channel region may be fabricated from other II-VI compound semiconductor materials including but not limited to zinc oxide, zinc selenide, zinc sulfide, cadmium selenide, cadmium sulfide or other complex oxide materials such as InGaZnO or zinc-tin-oxide. In addition, the transistor 20 is shown having a bottom-gate configuration (i.e., gate electrode position below the channel region). Likewise, it is contemplated that the transistor may employ other types of gate configurations.

Zinc telluride (ZnTe), an intrinsically p-type semiconductor due to zinc vacancies, is a II-VI compound that is compatible with ZnO and presents an opportunity for integration with n-type ZnO for complementary electronics. Thus, the channel region 35 of the p-type field effect transistor is fabricated from ZnTe material as further described below. The p-type field effect transistor 30 is disposed adjacent to the n-type field effect transistor 20 and operably coupled thereto, thereby forming a complementary semiconductor device.

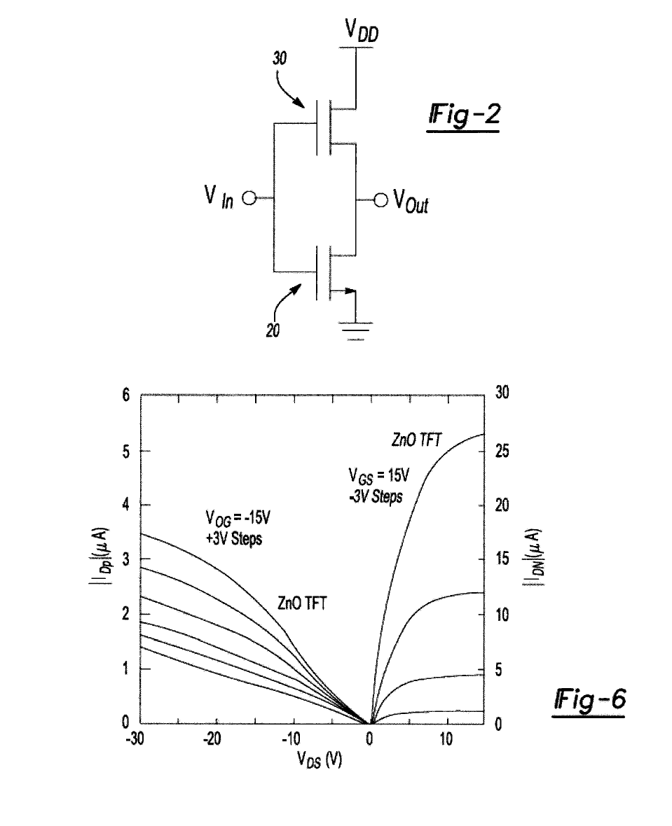

More specifically, the n-type field effect transistor 20 and p-type transistor 30 are coupled together to form a complementary inverter circuit as shown schematically in FIG. 2. In this arrangement, an input voltage (V_{IN}) may be applied to the gate electrodes of the transistors, where the gate electrodes are electrically coupled together. The source electrode of the p-type transistor is electrically connected to a supply voltage (V_{DD}); whereas, the source electrode of the n-type transistor is coupled to ground. An output voltage (V_{OUT}) for the inverter is derived from the drain electrodes which are electrically coupled together. It is readily appreciated that additional transistors may be coupled together to implemented other types of logic functions and circuits.

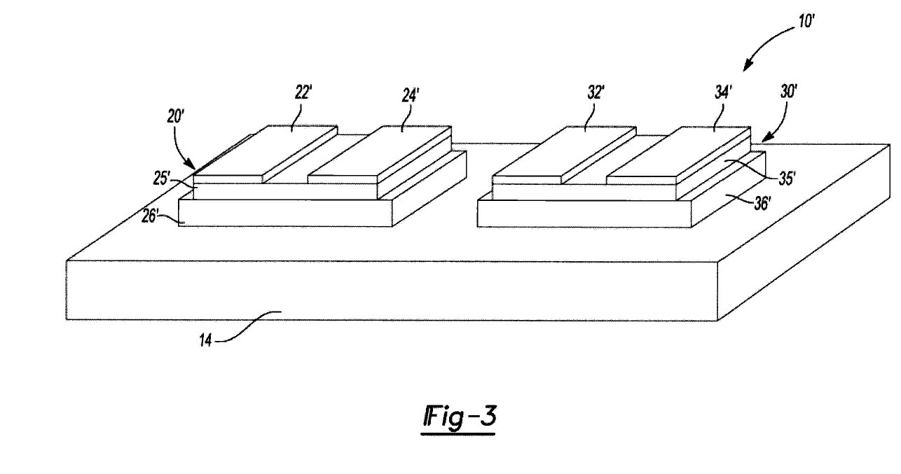

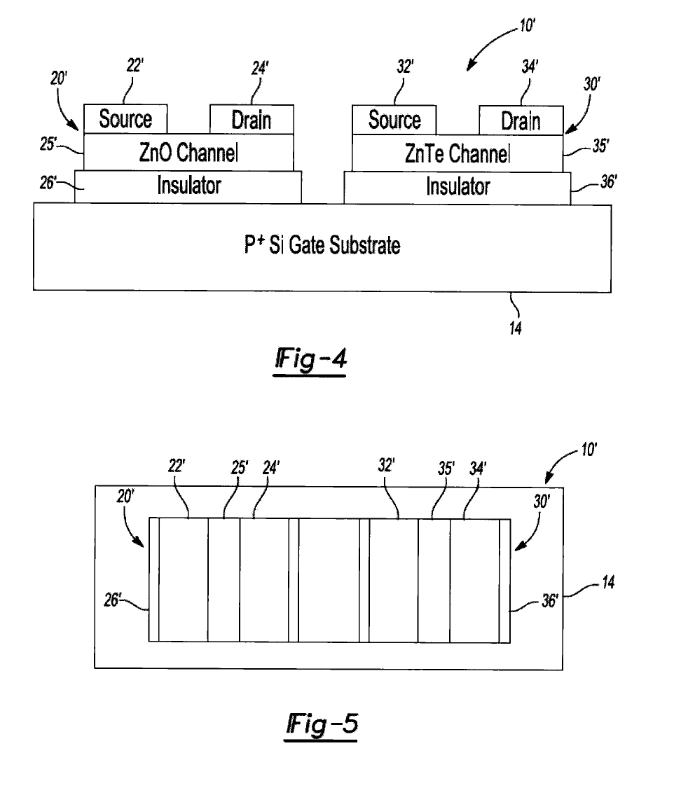

FIGS. 3-5 illustrate another exemplary complementary thin-film electronic device structure 10′. In this exemplary embodiment, a highly conductive (p+) silicon wafer 14 functions as the gate electrode. Gate insulating layers 26′, 36′ are positioned between the gate electrode layer 14 and the n-type and p-type transistors 20′, 30′, respectively. Otherwise, the construct of the electronic device is the same as described above in relation to FIG. 1.

An exemplary fabrication technique for this type of complementary thin-film electronic device is further described. For prototype purposes, separate wafers were used to fabricate each transistor structure and then the two structures were combined subsequently to form a single device structure. It is readily understood that the device can be fabricated on a single substrate as shown in the figures.

Polycrystalline ZnO active channel layers (e.g., 30 nm thick) were synthesized by pulsed-laser deposition (PLD) using an excimer laser (e.g., KrF, λ=248 nm). To form the exemplary embodiments, the excimer laser was operated at an energy density E_{d} of 0.7 J/cm² to ablate a ZnO target (99.999%) with an oxygen partial pressure of 30 mTorr at a rate near 0.3 nm/s. Synthesis of ZnO channel layers is not limited to PLD as it also can be deposited by sputtering, electron-beam evaporation, chemical vapor deposition, electrochemical solution deposition, close-space sublimation, ink-printing and so on.

For the formation of the ZnTe thin films, molecular beam epitaxy (MBE) was initially used for growth of the ZnTe active channel layers. ZnTe thin-film deposition by MBE at a rate near 0.3 nm/s involved the evaporation of Zn and Te source materials. Similarly, p type ZnTe channel also can be achieved by other deposition methods including but not limited to sputtering, pulsed-laser deposition, electron-beam evaporation, chemical vapor deposition, electrochemical solution deposition, close-space sublimation, and ink-printing. To further increase conductivity, the zinc telluride material may be doped with nitrogen. For example, nitrogen doping may be implemented using a plasma source at a substrate temperature (T_{sub}) of 250° C. With the substrate held at T_{sub}=200° C. and a comparable deposition rate, PLD proved to be a relatively inexpensive alternative method for sequential deposition of ZnTe thin films. The ZnTe films by PLD (E_{d}=0.4 J/cm²) were deposited under vacuum (10⁻⁶ Torr) with no intentional doping.

After deposition of the thin-film layers, the source and drain electrodes were formed on top of the thin-film layers. In the exemplary embodiments, Ti/Al/Au and Ni/Au electrodes were deposited by vacuum evaporation to form the source and drain electrodes on ZnO and ZnTe channel regions, respectively. Channel regions were patterned using photolithography and wet chemical etching. An isolation mesa etch, using an etch chemistry of H₃PO₄:H₂O₂:H₂O (1:1:10) for the ZnTe layer and HCl:H₂O (1:10) for the ZnO layer, was then performed to electrically isolate active device regions. In the exemplary embodiments, the channel regions were formed with a nominal channel width (IN) of 100 μm and length (L) of 15 μm. Lastly, X-ray diffraction (θ−2θ) was used to characterize the crystal structure of the thin films and indicated polycrystalline ZnO and ZnTe with a preferred (0002) and (111) orientation, respectively (not shown). It is readily understood that other fabrication techniques may be employed and fall within the scope of this disclosure.

Operating characteristics for these complementary thin-film electronic devices are set forth below. Drain current-voltage (I_{D}−V_{DS}) curves of ZnO and ZnTe TFTs for varying gate voltage are shown in FIG. 6. The drain current characteristics increase linearly at low drain bias and exhibit well-defined current-saturation behavior from V_{DS}=0-15 V for the ZnO TFT. In the case of the ZnTe TFT, nonlinearity in the output curves at low drain-to-source voltage (V_{DS}<5 V) is characteristic of large source/drain contact resistance (R_{c}) which limits device performance. Even so, the p-type channel TFT exhibits gate field effect with substantial drain-current in the OFF-state, suggesting high conductivity in the ZnTe layers. This was confirmed by Hall effect measurements for a series of ZnTe thin films on sapphire substrates with similar growth conditions. The hole concentration was nearly constant at 3-5×10¹⁷ cm⁻³ with hole mobility of 20-35 cm². V⁻¹·s⁻¹. Thus, the ZnTe films had large intrinsic hole carrier concentration and mobility resulting in high conductivity, σ=3 Ω⁻¹·cm⁻¹. An increase in conductivity associated with the ZnTe thin films is thought to be associated with zinc vacancies. Maximum drain-currents of 4 and 1.5 μA were measured for ZnTe TFTs with active channels (W/L=100/15) deposited by MBE and PLD, respectively, although only the ZnTe TFTs with MBE material will be discussed below.

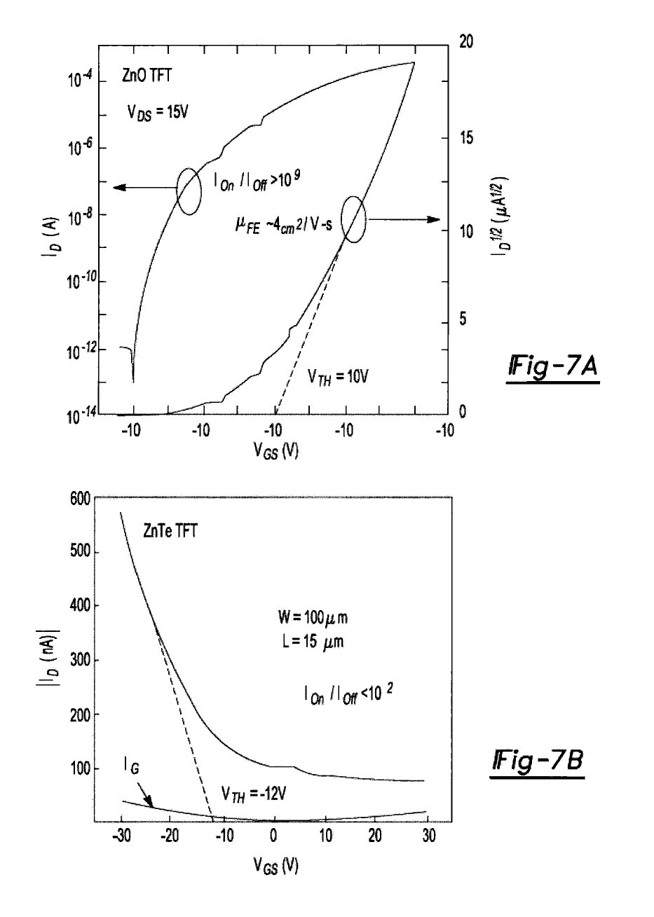

FIG. 7A shows the transfer curves I_{D}−V_{GS} and \sqrt{I_{D}}−V_{GS}, for the ZnO TFT while FIG. 7B is for the ZnTe TFT. The threshold voltage (Vₜₕ), field-effect mobility (μ_{FE}), and on/off-current ratio are all obtained from the expression I_{D}=(W/2L) μ_{FE}C_{INS} (V_{GS}−V_{TH})², for the device operated in saturation, where Cᵢₙₛ (˜300 nF/μm²) is the capacitance per unit area of the gate insulator. The estimated saturation μ_{FE} for the ZnO TFT was 3.7 cm²/V·s, while that for the ZnTe TFT is 0.1 cm²/V·s. Significant drain voltage drop across the source/drain contacts due to large R_{c} (>10³ Ω·cm) leads to an artifically small value for the extracted field-effect mobility. Moreover, charge trapping at the ZnTe/SiO₂ interface suppresses carrier transport in the TFT channel. The on/off-current ratios are 10⁹ and 10² while Vₜₕ are 10 and −12 V for the ZnO and ZnTe TFTs, respectively. These results support that both TFTs operate as depletion-mode (normally on) devices with an off current of 0.1 pA in the case of ZnO. High gate leakage current (I_{G}) and high conductivity in the ZnTe thin film limit the off current in the ZnTe TFT. Further improvements in device performance are expected to result from contact technology development and higher gate dielectric quality.

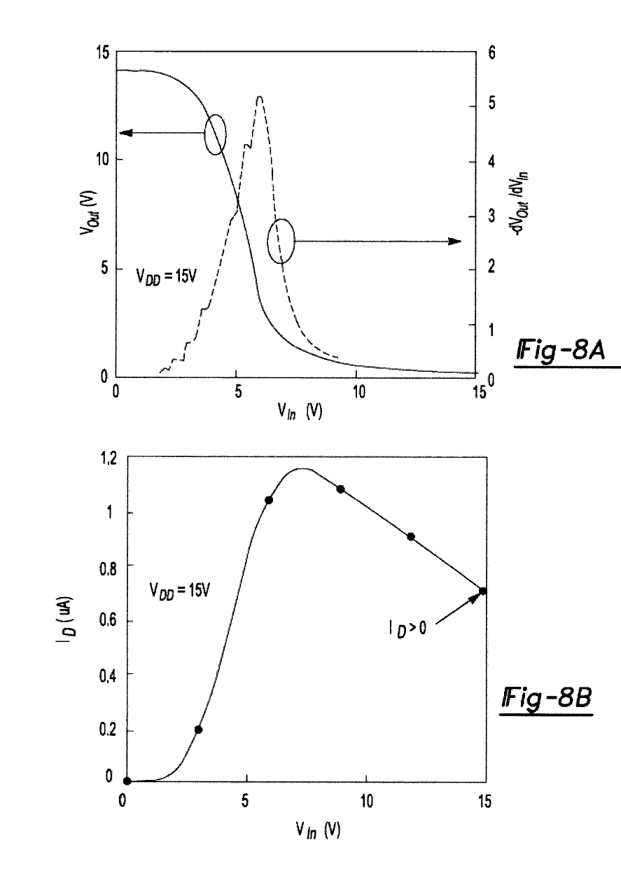

The voltage transfer characteristic (VTC) and voltage gain for static operation of the complementary TFT inverter circuit are shown in FIG. 8A by electrically connecting the p-ZnTe and n-ZnO devices. Inverter behavior is demonstrated with a high output voltage of V_{OH}>14 V and low output voltage of V_{OL}<0.2 V for a supply voltage of V_{DD}=15 V. The transition region gain for the transfer characteristic is found to be dVₒᵤₜ/dVᵢₙ>5 at a switching threshold of Vᵢₙ=6 V. In the case of the high-output state, the inability of the inverter to reach V_{DD} is limited by a turn-on voltage of less than zero for the ZnO TFT and to a greater degree the gate leakage current for the ZnTe TFT. Moreover, a switching threshold voltage less than V_{DD}/2 suggests the impact of inferior operating performance from the ZnTe TFT and/or non-optimal device geometry to match drain current for p-channel and n-channel devices. High off current for the ZnTe TFT yields a low-output state greater than zero evident from high inverter current (I_{D}) for Vᵢₙ=15 V, as shown in FIG. 8B. Despite the inferior transistor behavior of the ZnTe device, incorporation of the ZnTe and ZnO TFTs in a complementary logic inverter circuit demonstrates reasonable transfer characteristics.

Static-inverter behavior has been demonstrated for V_{DD}=15 V and dVₒᵤₜ/dVᵢₙ˜5 by incorporating ZnTe and ZnO TFTs in a complementary logic circuit. ZnO TFTs exhibited a field-effect mobility of μ_{FE}=4 cm²/V·s and Iₒₙ/I_{off}>10⁹. ZnTe TFTs fabricated by MBE and PLD were demonstrated with Iₒₙ/I_{off}>10² limited by high off current and contact resistance.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

What is claimed is:

1. A complementary semiconductor device, comprising:
a first field effect transistor residing on a substrate and having an n-type channel region fabricated from a II-VI compound semiconductor material; and
a second field effect transistor residing on the substrate and having a p-type channel region fabricated from zinc telluride material, wherein a drain electrode of the second field effect transistor is electrically coupled to a drain electrode of the first field effect transistor.

2. The semiconductor device of claim 1 wherein the zinc telluride material is doped with nitrogen to increase conductivity.

3. The semiconductor device of claim 1 wherein the II-VI compound semiconductor material is further defined as zinc oxide.

4. The semiconductor device of claim 1 wherein the II-VI compound semiconductor material is selected from a group consisting of zinc oxide, zinc selenide, zinc sulfide, cadmium selenide, and cadmium sulfide.

5. The semiconductor device of claim 1 wherein a gate electrode for the first field effect transistor is electrically coupled to a gate electrode for the second field effect transistor.

6. The semiconductor device of claim 1 wherein the first and second field effect transistors have a bottom gate configuration.

7. The semiconductor device of claim 1 wherein the first and second field effect transistors are further defined as metal oxide semiconductor transistors.

8. A complementary semiconductor device, comprising:
a substrate
a n-type field effect transistor having a n-type channel region and disposed on the substrate; and
a p-type field effect transistor disposed on the substrate adjacent to the n-type field effect transistor and operably coupled thereto, the p-type field effect transistor having a p-type channel region fabricated from zinc telluride material.

9. The semiconductor device of claim 8 wherein the zinc telluride material is doped with nitrogen to increase conductivity.

10. The semiconductor device of claim 9 wherein n-type field effect transistor having a n-type channel region fabricated from a II-VI compound semiconductor material.

11. The semiconductor device of claim 9 wherein n-type field effect transistor having a n-type channel region fabricated from a material selected from a group consisting of zinc oxide, zinc selenide, zinc sulfide, cadmium selenide, and cadmium sulfide.

12. The semiconductor device of claim 8 wherein the n-type and p-type field effect transistors have a bottom gate configuration.

13. The semiconductor device of claim 8 wherein drain electrodes for the n-type and p-type field effect transistor are electrically coupled together and gate electrodes for the n-type and p-type field effect transistors are electrically coupled together.

14. The semiconductor device of claim 8 wherein the n-type and p-type field effect transistors are further defined as metal oxide semiconductor transistors.

15. A complementary inverter circuit, comprising:
a p-type field effect transistor having a source electrode, a drain electrode, a gate electrode and a channel region, where the channel region is fabricated from zinc telluride material
a n-type field effect transistor having a source electrode, a drain electrode, a gate electrode and a channel region, where the gate electrodes for the n-type and p-type field effect transistors are electrically coupled to an input voltage and to each other, and the drain electrodes for the n-type and p-type field effect transistor are electrically coupled together to form an output terminal.

16. The inverter circuit of claim 15 wherein the zinc telluride material is doped with nitrogen to increase conductivity.

17. The inverter circuit of claim 15 wherein n-type field effect transistor having a n-type channel region fabricated from zinc oxide material

18. The inverter circuit of claim 15 wherein the n-type and p-type field effect transistors are further defined as metal oxide semiconductor transistors.
